(19) United States
(12) Patent Application Publication
(10) Pub. No.: US 2018/0358576 A1
(43) Pub. Date: Dec. 13, 2018

(54) POLARIZATION OPTICAL ASSEMBLY, OLED DEVICE AND PREPARATION METHOD THEREOF, AND DISPLAY DEVICE

(71) Applicant: BOE TECHNOLOGY GROUP CO., LTD., Beijing (CN)

(72) Inventors: Ping SONG, Beijing (CN); Feifei WANG, Beijing (CN); Youwei WANG, Beijing (CN); Peng CAI, Beijing (CN); Yuanzheng GUO, Beijing (CN)

(21) Appl. No.: 15/736,530

(22) PCT Filed: Jul. 7, 2017
(86) PCT No.: PCT/CN2017/092211

§ 371 Date: Dec. 14, 2017

(30) Foreign Application Priority Data
Jul. 8, 2016 (CN) 201610539561.8

(51) Int. Cl. H01L 51/52; G02B 5/30; H01L 51/56

(52) U.S. Cl. CPC H01L 51/5262; H01L 51/56; G02B 5/3016

(57) ABSTRACT

A polarization optical assembly, an OLED device and a preparation method thereof, a display device. The polarization optical assembly includes: a cholesteric liquid crystal layer, a λ/4 wave plate and a linear polarizer. The λ/4 wave plate is between the cholesteric liquid crystal layer and the linear polarizer, and an angle exists between a fast axis or a slow axis of the λ/4 wave plate and a transmission axis of the linear polarizer, and polarized light formed by external fight sequentially passing the linear polarizer and the λ/4 wave plate is able to pass through the cholesteric liquid crystal layer. The display device can increase the output of light while reducing the reflection of external light.

### TECHNICAL FIELD

Embodiments of the present disclosure relate to a polarization optical assembly, an OLED device and a preparation method thereof, and a display device.

### BACKGROUND

OLED (Organic Light Emitting Diode) device is an organic thin film electroluminescent device and has advantages such as simple preparation process, low cost, low power consumption, high brightness, wide working temperature range, small volume, fast response, easy for forming a flexible structure and wide angle of view etc.; therefore, a display technology based on organic light emitting diode (OLED) has become an important display technology.

An OLED (Organic Light Emitting Diode) device comprises a cathode, an organic functional layer and an anode, and the cathode is generally formed by metal or metal alloy. Due to the high reflectivity of metal or metal alloy to external light, the display brightness of the OLED device felt by human eyes is the sum of the predetermined display brightness and the brightness of external light reflected by the metal cathode to the human eyes when the light emitted by the organic functional layer is emitted through the cathode, that is, the display brightness of the OLED device has suffered from a deviation, which thus affects the display effect of the OLED device.

### SUMMARY

An embodiment of the present disclosure provides a polarization optical assembly, an OLED device and a preparation method thereof, a display device, and the display device can increase the output of light while reducing the reflection of external light.

In one aspect, an embodiment of the present disclosure provides a polarization optical assembly, comprising: a cholesteric liquid crystal layer, a λ/4 wave plate and a linear polarizer, wherein the λ/4 wave plate is between the cholesteric liquid crystal layer and the linear polarizer, and an angle exists between a fast axis or a slow axis of the λ/4 wave plate and a transmission axis of the linear polarizer, and polarized light formed by external light sequentially passing the linear polarizer and the λ/4 wave plate is able to pass through the cholesteric liquid crystal layer.

Optionally, the cholesteric liquid crystal layer is a polymer film formed through polymerization of cholesteric liquid crystals.

Optionally, the cholesteric liquid crystal layer comprises at least two types of cholesteric liquid crystals with different pitches.

Optionally, the cholesteric liquid crystal layer comprises a plurality of sub-layers, and pitches of all the sub-layers are distributed in a gradient along a thickness direction.

Optionally, the cholesteric liquid crystal layer comprises cholesteric liquid crystals with a single pitch.

Optionally, the angle between the fast axis or the slow axis of the λ/4 wave plate and the transmission axis of the linear polarizer is 45°.

In another aspect, another embodiment of the present disclosure provides an OLED device, comprising a light-emitting element and the polarization optical assembly mentioned above, and the polarization optical assembly is arranged on the light-emitting side of the light-emitting elements.

Optionally, the light-emitting element comprises: a cathode, an anode and an organic functional layer arranged between the cathode and the anode, and light emitted by the organic functional layer exits at least through the cathode.

Optionally, the polarization optical assembly is on a side of the cathode away from the organic functional layer and the cholesteric liquid crystal layer of the polarization optical assembly is configured to reflect part of the light emitted by the organic functional layer.

Optionally, the organic functional layer comprises: a light-emitting layer, a hole injection layer arranged between the light-emitting layer and the anode, and an electron injection layer arranged between the light-emitting layer and the cathode.

Optionally, the organic functional layer further comprises: a hole-transporting layer arranged between the hole injection layer and the light-emitting layer, an electron-transporting layer arranged between the electron injection layer and the light-emitting layer.

In still another aspect, another embodiment of the present disclosure provides a display device, comprising a plurality of sub-pixels, and each of the sub-pixels comprises any one of the OLED devices described above.

Optionally, all polarization optical assemblies of the OLED devices are in an integrated structure.

In further still another aspect, another embodiment of the present disclosure provides a preparation method of an OLED device, comprising: providing a light-emitting element, and forming a polarization optical assembly on a light-emitting side of the light-emitting element.

Optionally, providing the light-emitting element comprises: providing a base substrate; forming an anode, an organic functional layer and a cathode sequentially on the base substrate, wherein light emitted by the organic functional layer exits at least through the cathode.

Optionally, forming the polarization optical assembly on the light-emitting side of the light-emitting elements comprises: forming the polarization optical assembly on a side of the cathode away from the organic functional layer, wherein a cholesteric liquid crystal layer of the polarization optical assembly is configured to be able to reflect part of the light emitted by the organic functional layer.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic diagram of a light path on which external light is reflected by an OLED device;

FIG. 2 is a schematic diagram of a light path on which the light emitted by the organic functional layer of the OLED device as illustrated in FIG. 1 is transmitted to the external environment;

FIG. 3 is a structural schematic diagram of a polarization optical assembly provided by an embodiment of the present disclosure;

FIG. 4 is schematic diagram 1 of the cholesteric liquid crystal layer illustrated in FIG. 3;

FIG. 5 is schematic diagram 2 of the cholesteric liquid crystal layer illustrated in FIG. 3;

FIG. 6 is schematic diagram 3 of the cholesteric liquid crystal layer illustrated in FIG. 3;

FIG. 7 is a structural schematic diagram of an OLED device provided by an embodiment of the present disclosure;

FIG. 8 is a schematic diagram of a light path on which external light enters the OLED device illustrated in FIG. 7 and then is reflected out;

FIG. 9 is a schematic diagram of a light path on which the light emitted by the organic functional layer of the OLED device illustrated in FIG. 1 is transmitted to the external environment; and

FIG. 10 is a structural schematic diagram of another OLED device provided by an embodiment of the present disclosure.

### REFERENCE NUMBERS OF DRAWINGS

1—cathode; 2—organic functional layer; 3—anode; 4—circular polarizer; 5—linear polarizer; 6—λ/4 wave plate; 7—polarization optical assembly; 8—cholesteric liquid crystal layer; 9—light-emitting layer; 10—hole injection layer; 11—electron injection layer; 14—sub-layer of cholesteric liquid crystal layer.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment (s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

It should be noted that “left-helical” or “right-helical” mentioned in embodiments of the present disclosure are all obtained in observing on the same observation direction.

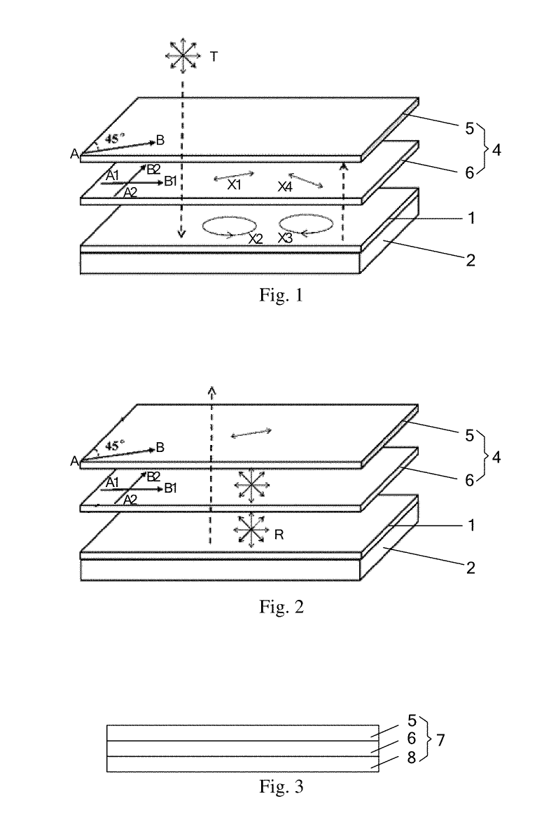

FIG. 1 is a schematic diagram of a light path on which external light is reflected by an OLED device. For example, referring to FIG. 1, the above-mentioned problem can be reduced by providing a circular polarizer 4 (for example, the polarizer 4 can be formed by the combination of a linear polarizer 5 and a λ/4 wave plate 6) on a side of a cathode 1 away from an organic functional layer 2. Referring to FIG. 1, light parallel to a transmission axis (that is, polarization direction) of the linear polarizer 5 in external light T can pass through the linear polarizer 5, and light perpendicular to the transmission axis of the linear polarizer 5 is absorbed by the linear polarizer 5; that is, the external light T is changed into the linear polarized light X1 whose polarization direction is parallel to the transmission axis of the linear polarizer 5 after passing through the linear polarizer 5. When the angle between the fast axis or the slow axis of the λ/4 wave plate 6 and the transmission axis of the linear polarizer 5 is 45°, the angle between the polarization direction of the linearly polarized light X1 and the fast axis or the slow axis of the λ/4 wave plate 6 is 45°, and the linearly polarized light X1 is changed into right-helical or left-helical circularly polarized light X2 after passing through the λ/4 wave plate 6 (the description is conducted by taking as an example left-helical circularly polarized light herein); the left-helical circularly polarized light X2 is changed into right-helical circularly polarized light X3 after being reflected by the cathode 1; the right-helical circularly polarized light X3 is changed into linearly polarized light X4 after passing through the λ/4 wave plate 6, and the angle between the polarization direction of the linearly polarized light X4 and the fast axis or the slow axis of the λ/4 wave plate 6 is −45°. Then, the polarization direction of the linearly polarized light X4 is perpendicular to the polarization direction of the linearly polarized light X1, that is, the polarization direction of the linearly polarized light X4 is perpendicular to the transmission axis of the linear polarizer 5, so that the linearly polarized light X4 is absorbed by the linear polarizer 5 and is not able to exit. Therefore, it can prevent external light from being reflected to human eyes by the metal cathode so as to improve outdoor readability.

FIG. 2 is a schematic diagram of a light path on which the light emitted by the organic functional layer of the OLED device as illustrated in FIG. 1 is transmitted to the external environment. For example, referring to FIG. 2, light R emitted by the organic functional layer 2 of the OLED device comprises light in all polarization states, such as linearly polarized light, elliptically polarized light and circularly polarized light. After the light R passes through the cathode 1 and the λ/4 wave plate 6, the overall polarization of the light R is not changed in general; then, after the above-mentioned light passes through the linear polarizer 5, only light parallel to the polarization direction of the linear polarizer 5 can pass through the linear polarizer 5 and be used for display, while light perpendicular to the polarization direction of the linear polarizer 5 is absorbed by the linear polarizer 5. Therefore, after light emitted by the organic functional layer of the OLED device passes the circular polarizer as illustrated in FIG. 1 or FIG. 2, the intensity of the light can be reduced by at least half, causing significant reduction in the display brightness of the OLED device.

The present disclosure provides a polarization optical assembly, an OLED device and a preparation method thereof, a display device, and the polarization optical assembly can increase the light output ratio of the OLED device and the display device which comprise the polarization optical assembly. The polarization optical assembly, the OLED device and the preparation method thereof, the display device according to embodiments of the present disclosure are explained by reference to several embodiments below.

### Embodiment One

An embodiment of the present disclosure provides a polarization optical assembly, referring to FIG. 3, a polarization optical assembly 7 comprises: a liquid crystal layer 8 (for example, a cholesteric liquid crystal layer 8), a λ/4 wave plate 6 and a linear polarizer 5; the λ/4 wave plate 6 is between the cholesteric liquid crystal layer 8 and the linear polarizer 5, and an angle exists between a fast axis or a slow axis of the λ/4 wave plate and a transmission axis of the linear polarizer, and polarized light formed by external light sequentially passing the linear polarizer and the λ/4 wave plate is able to pass through the cholesteric liquid crystal layer.

Generally, two directions are defined in a wave plate, i.e., the fast axis or the slow axis. The propagation velocity of light whose polarization direction is along the fast axis is faster, and the direction perpendicular to the fast axis is the slow axis, that is, the propagation velocity of light whose polarization direction is along the slow axis is slower. If the angel between the fast axis or the slow axis of the λ/4 wave plate and the transmission axis of the linear polarizer is 45°, external light is changed into left-helical (or right-helical) circularly polarized light after the external light sequentially passing the linear polarizer and the λ/4 wave plate. If the angel between the fast axis or the slow axis of the λ/4 wave plate and the transmission axis of the linear polarizer is α (α≠45°), the external light is changed into left-helical (or right-helical) elliptically polarized light after the external light sequentially passing the linear polarizer and the λ/4 wave plate. The above-mentioned linear polarizer only permits light whose polarization direction is parallel to the transmission axis of the linear polarizer to pass through itself and filters the light whose polarization direction is perpendicular to the transmission axis of the linear polarizer out at the same time. The transmission axis can be also called a polarization axis herein.

Cholesteric liquid crystal molecules are flat and arranged into layers, and the molecules in the layers are parallel to each other, and the molecular long axis is parallel to the layer plane, and the direction of the molecular long axis varies slightly in different layers, and the molecular long axes are arranged in a heliciform structure along the normal direction of the layer. The heliciform structure is left-helical or right-helical. According to the helical direction of the heliciform structure, cholesteric liquid crystal layer can be divided into left-helical cholesteric liquid crystal layer and right-helical cholesteric liquid crystal layer.

Polarized light formed by external light sequentially passing the linear polarizer and the λ/4 wave plate is able to pass through the cholesteric liquid crystal layer, which means that left-helical or right-helical polarized light formed by the external light sequentially passing the linear polarizer and the λ/4 wave plate is able to totally or partly pass through the cholesteric liquid crystal layer. That is, the helical direction of polarized light formed by the external light sequentially passing the linear polarizer and the λ/4 wave plate is the same as the helical direction of the cholesteric liquid crystal layer.

When the above-mentioned polarization optical assembly is applied in a display device, the display device can increase the output of light while reducing the reflection to external light.

Optionally, in order to reduce the manufacture cost, the above-mentioned cholesteric liquid crystal layer is a polymer film formed by polymerization of cholesteric liquid crystals which can be polymerized.

The concept of pitch is explained below. Cholesteric liquid crystal comprises many layers of molecules, orientations of molecules in each layer are the same, but orientations of molecules in two adjacent layers have slight rotation, and the layers stack into a heliciform structure in general. When the orientation of the molecules rotates 360° and returns back to the original orientation, the distance between two layers in which the orientations of molecules are exactly the same is called the pitch of the cholesteric liquid crystal. According to actual requirements, a chiral material(s) can be added to the cholesteric liquid crystal to change the pitch thereof. A cholesteric liquid crystal layer can comprise a plurality of cholesteric liquid crystals with different pitches, and also can comprise cholesteric liquid crystals with a single pitch, specific is determined according to the actual situation. If the wavelength of incident light is consistence with the pitch of the cholesteric liquid crystal, the cholesteric liquid crystal permits the incident light whose helical direction is consistent with the helical direction of the cholesteric liquid crystal to pass through it and reflect the incident light whose helical direction is opposite to the helical direction of the cholesteric liquid crystal. If the wavelength of incident light is not consistent with the pitch of the cholesteric liquid crystal, the cholesteric liquid crystal permits all the incident light to pass through it. Therefore, the situation of reflection or transmission of the incident light can be changed by adjusting the pitch.

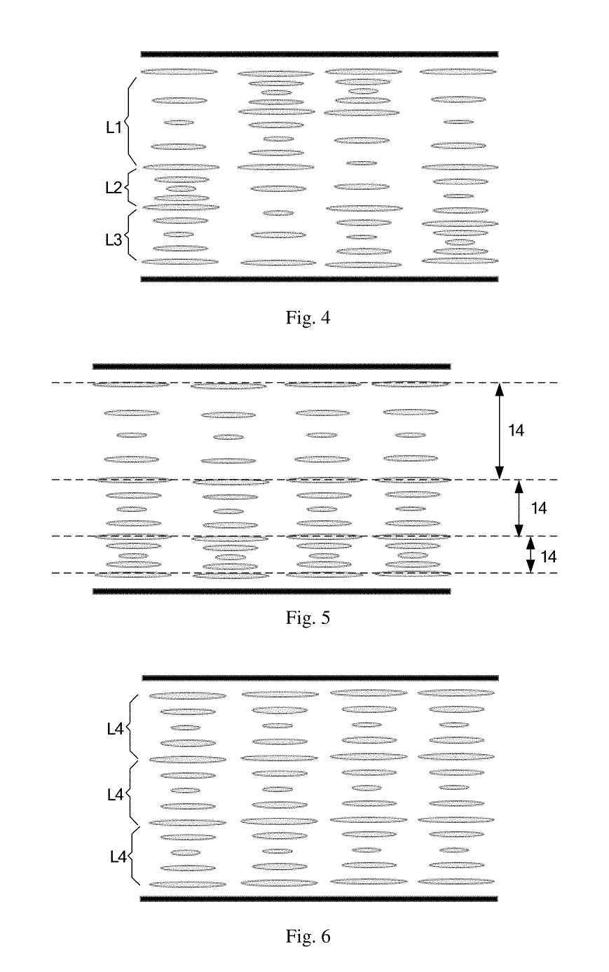

Optionally, the cholesteric liquid crystal layer comprises at least two types of cholesteric liquid crystals with different pitches. The pitches of the cholesteric liquid crystals can be in random distribution as illustrated in FIG. 4 or can be distributed according to a certain rule as illustrated in FIG. 5. The pitch of this type of cholesteric liquid crystal layer can be adjusted so that the cholesteric liquid crystal layer can reflect the whole visible light wave spectrum and then it can be applied in color OLED displays.

Optionally, referring to FIG. 5, the cholesteric liquid crystal layer comprises a plurality of sub-layers, and pitches of all the sub-layers are distributed in a gradient along a thickness direction. Herein, the cholesteric liquid crystal layer can comprise two sub-layers, or it can comprise three sub-layers as illustrated in FIG. 5, and it also can comprise more than three sub-layers, which is not limited. The gradient distribution herein can mean that the pitches of all the sub-layers are sequentially reduced or sequentially increased along the thickness direction, and FIG. 5 is conducted by taking as an example of stepwise reduction.

Optionally, referring to FIG. 6, the cholesteric liquid crystal layer comprises cholesteric liquid crystals with a single pitch. The pitch of this type of cholesteric liquid crystal layer can be adjusted so that the cholesteric liquid crystal layer can reflect the particular wave spectrum and then it can be applied in various monochromatic OLED displays.

It should be noted that the pitches in FIG. 4 and FIG. 6 are represented by L1, L2, L3, L4, and the different numbers represents different amplitude.

Optionally, in order to reduce the degree of difficulty of manufacturing, the angle between the fast axis or the slow axis of the λ/4 wave plate and the transmission axis of the linear polarizer is 45°. With this structure, external light is changed into left-helical (or right-helical) circularly polarized light after sequentially passing through the linear polarizer and the λ/4 wave plate.

### Embodiment Two

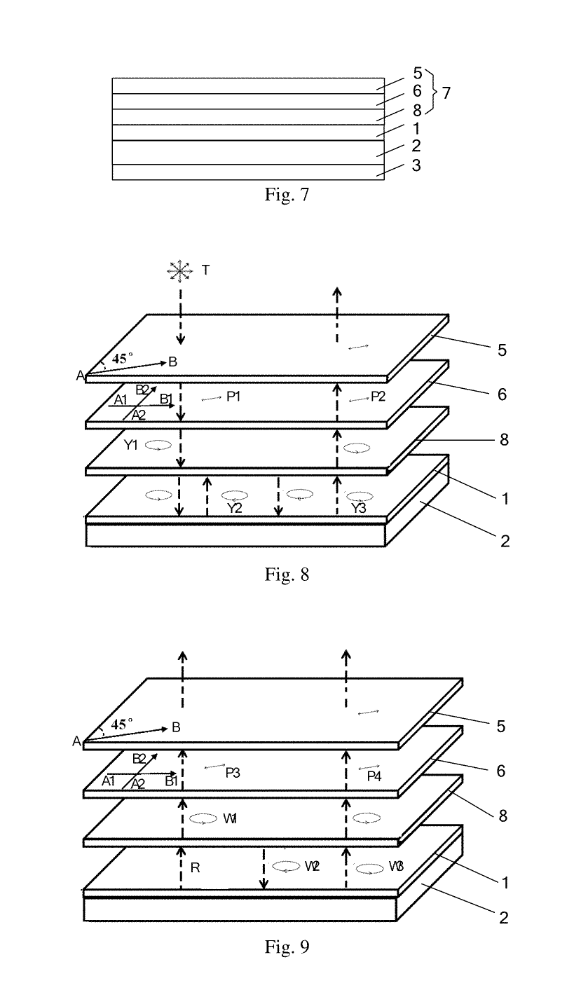

This embodiment of the present disclosure provides an OLED device, referring to FIG. 7, the OLED device comprises a light-emitting element and the polarization optical assembly 7 provided by embodiment one. The light-emitting element can comprise a cathode 1, an anode 3 and an organic functional layer 2 arranged between the cathode 1 and the anode 3. Material of the cathode 1, for example, can be metal or metal alloy. Light emitted by the organic functional layer 2 is transmitted out at least through the cathode 1; the polarization optical assembly 7 are on a side of the cathode 1 away from the organic functional layer 2 and the cholesteric liquid crystal layer 8 of the polarization optical assembly 7 can reflect part of the light emitted by the organic functional layer 2.

The above-mentioned cholesteric liquid crystal layer of the polarization optical assembly is configured to reflect part of the light emitted by the organic functional layer, so at least part of the pitch values of the cholesteric liquid crystals contained in the cholesteric liquid crystal layer are consistent with the wavelength of the light emitted by the organic functional layer; the light emitted by the organic functional layer can be divided into left-helical polarized light and right-helical polarized light, and the cholesteric liquid crystal can reflect the light whose helical direction is opposite to the helical direction of the cholesteric liquid crystal and permit the light whose helical direction is the same as the helical direction of the cholesteric liquid crystal to pass through. For example, the cholesteric liquid crystal layer is left-helical, at least part of the pitch values of the cholesteric liquid crystals contained in the cholesteric liquid crystal layer are consistent with the wavelength of the light emitted by the organic functional layer, in that way, the left-helical polarized light emitted by the organic functional layer can pass through the cholesteric liquid crystal layer, but the right-helical polarized light emitted by the organic functional layer is reflected by the cholesteric liquid crystal layer.

In the above-mentioned OLED device, embodiments of the present disclosure do not limit the relative position between the cathode and the anode, for example, referring to FIG. 7, the cathode 1 can be arranged above the anode 3; of course, the cathode 1 also can be arranged under the anode 3. The description is conducted only by taking as an example the structure as illustrated in FIG. 7 herein. Light emitted by the organic functional layer exits at least through the cathode, which means that light emitted by the organic functional layer can be transmitted through the cathode only so as to form a single side light-emitting device; of cause, light emitted by the organic functional layer also can exit through the cathode and the anode so as to form a double-side light emitting device; the embodiments of the present disclosure are not limited in this aspect.

In the above-mentioned OLED device, embodiments of the present disclosure do not limit the material of the cathode, for example, the material of the cathode can be metal, such as magnesium (Mg), silver (Ag), aluminum (Al), lithium (Li), potassium (K) or calcium (Ca) etc., or it also can be metal alloy, such as magnesium-silver alloy, lithium-aluminum alloy etc. In addition, embodiments of the present disclosure do not limit the material of the anode, either. Commonly, the material of the anode is mostly ITO (indium-tin oxide), so that it is beneficial to the injection of holes into the organic functional layer.

By taking as an example the case in which left-helical polarized light is formed after external light sequentially passes through the linear polarizer and the λ/4 wave plate and the cholesteric liquid crystal layer is left-helical, it is explained how the above-mentioned OLED device increases the output of light as well as reducing the reflection of external light.

The light path on which external light enters the OLED device and then is reflected out is explained first.

Referring to FIG. 8, after external light T enters the linear polarizer 5, linearly polarized light P1 parallel to the polarization direction of the linear polarizer 5 in the external light T passes through the linear polarizer 5, and light S perpendicular to the polarization direction of the linear polarizer 5 is absorbed. The linearly polarized light P1 which has passed through is changed into left-helical or right-helically polarized light Y1 (the description is conducted by taking as an example left-helically polarized light herein), the left-helically polarized light Y1 can pass through the cholesteric liquid crystal layer 8 (left-helical) and then is changed into right-helically polarized light Y2 by the reflection by the cathode 1. The right-helically polarized light Y2 is reflected by the cholesteric liquid crystal layer 8 (left-helical) and then is changed into left-helically polarized light Y3 after being reflected by the cathode 1. The left-helically polarized light Y3 passes through the cholesteric liquid crystal layer 8 (left-helical) and then is changed into linearly polarized light P2 whose polarization direction is parallel to the light P1 after passing through the λ/4 wave plate 6. Finally, the linearly polarized light P2 reaches the external environment.

The reflectivity of the above-mentioned OLED device to external light is calculated by taking as an example the case that the transmissivity of the λ/4 wave plate is 98%, the reflectivity of the cathode is 40%, the transmissivity of the linear polarizer to the light P2 and the light P1 is 98%, the transmissivity of the cholesteric liquid crystal layer (left-helical) to left-helically polarized light is 90%, and the reflectivity of the cholesteric liquid crystal layer (left-helical) to right-helically polarized light is 90%.

The reflectivity of the above-mentioned OLED device to external light is:

the transmissivity after the external light T passes through the linear polarizer is 98%*50% (the ratio between the light P1 and the light S in the external light T is 1:1);

the transmissivity after the linearly polarized light P1 passes through the λ/4 wave plate is 98%;

the transmissivity after the left-helically polarized light Y1 passes through the cholesteric liquid crystal layer is 90%;

the probability that the left-helically polarized light Y1 is reflected by the cathode is 40%;

the probability that the right-helically polarized light Y2 is sequentially reflected by the cholesteric liquid crystal layer and the cathode is 90%*40%;

the transmissivity after left-helically polarized light Y3 sequentially passes through the cholesteric liquid crystal layer and the λ/4 wave plate is 90%*98%; and

the transmissivity after the linearly polarized light P2 passes through the linear polarizer is 98%;

then the final reflectivity is:

98%*50%*98%*90%*40%*90%*40%*90%*98%*98%=5.3%

Because the loss of light in the propagation is not taken in account in the above calculation method, the maximum reflectivity of external light is 5.3% in the structure of the present disclosure. However, in the structure as illustrated in FIG. 1 which is in the art of state, the reflectivity is about 4%˜5%, that is, the present disclosure can guarantee low reflectivity to external light, that is, it can reduce reflection of external light.

The light path on which light is emitted out of the OLED device is explained then.

Referring to FIG. 9, light R is emitted by the organic functional layer 2 of the OLED device. The light R can be divided into left-helically polarized light and right-helically polarized light according to the ratio of 1:1. The type of light emitted by the OLED device can be set according to the actual application requirements and the present disclosure is not limited in this aspect; for example, according to the actual application requirements, OLED device can emit linearly polarized light, but embodiments of the present disclosure are not limited to this case; for another example, according to the actual application requirements, OLED device also can emit light of other types, for example, mixed light of various polarized light. For example, after the light R passes through the cholesteric liquid crystal layer 8 (left-helical), left-helical polarized light W1 passes therethrough and right-helical polarized light W2 is reflected. On the one hand, the left-helical polarized light W1 is changed into linearly polarized light P3 whose polarization direction is parallel to the polarization direction of the linear polarizer 5 after passing through the λ/4 wave plate 6, and the light P3 reaches the external environment after passing through the linear polarizer 5; on the other hand, after right-helical polarized light W2 is reflected by the cholesteric liquid crystal layer 8 (left-helical), it changes its direction of propagation, and is transmitted onto the cathode 1 and then changed into left-helical polarized light W3 after being reflected by the cathode 1. At this time, the left-helically polarized light W3 can pass through the cholesteric liquid crystal layer 8 (left-helical) and then is changed into linearly polarized light P4 whose polarization direction is parallel to polarization direction of the linear polarizer 5 after passing through the λ/4 wave plate 6, and the linearly polarized light P4 reaches the external environment after passing through the linear polarizer 5.

In the same way, the reflectivity of the above-mentioned OLED device to external light is calculated by taking as an example in the case that the transmissivity of the λ/4 wave plate is 98%, the reflectivity of a metal electrode is 40%, the transmissivity of the linear polarizer to the light P is 98%, the transmissivity of the cholesteric liquid crystal layer (left-helical) to left-helically polarized light is 90%, and the reflectivity of the cholesteric liquid crystal layer (left-helical) to right-helically polarized light is 90%.

The proportion of the light P3 in the light emitted by the organic functional layer is: 45%*98%*98%=43.2%; the proportion of the light P4 in the light emitted by the organic functional layer is: 45%*40%*90%*98%*98%=15.6%; that is, the total output ratio of light is 43.2%+15.6%=58.8%. However, in the structure as illustrated in FIG. 1 which is in the art of state, the output ratio of light is: 98%*50%*98%=48%.

After comparing the above data, it is found that the output ratio of light of the OLED device provided by the present disclosure is increased by 22.5%. Compared with the art of state, the present disclosure allows part of the light emitted by the organic functional layer, which part would not be available originally, to be transmitted to the outside and re-used by adding the cholesteric liquid crystal layer between the cathode and the λ/4 wave plate, notably increasing the output of light.

In summary, the output ratio of light of the OLED device provided in the present disclosure is up to 58.8%, and the maximum reflectivity to external light is 5.3%; however, the output ratio of light is 48% and the reflectivity to external light is about 4%-5% in the art of state; after comparing the above data, it is found that the output ratio of light of the OLED device provided by the present disclosure is increased by 22.5%, and it can guarantee lower reflectivity to external light at the same time. That is the OLED device provided by the present disclosure can increase the output of light while reducing the reflection of external light.

It should be noted that the direction of the transmission axis of the linear polarizer 5 is the same as the direction of A-B, and the fast axis and the slow axis of the λ/4 wave plate are the same as the direction of A1-B1 and the direction of A2-B2 respectively in FIG. 1, FIG. 2, FIG. 8 and FIG. 9. The description is conducted in embodiments and figures of the present disclosure by taking as an example of the case that the fast axis or the slow axis of the λ/4 wave plate and the transmission axis of the linear polarizer is 45°.

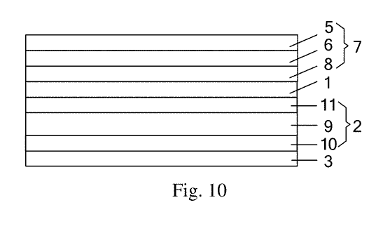

Referring to FIG. 10, the organic functional layer 2 comprises: a light-emitting layer 9, a hole injection layer 10 arranged between the light-emitting layer 9 and the anode 3, and an electron injection layer 11 arranged between the light-emitting layer 9 and the cathode 1. The hole injection layer is beneficial to inject holes from the anode into the light-emitting layer, and the electron injection layer is beneficial to inject electrons from the cathode into the light-emitting layer, so that the output ratio of light is improved.

Optionally, the organic functional layer further comprises: a hole-transporting layer arranged between the hole injection layer and the light-emitting layer, and an electron-transporting layer arranged between the electron injection layer and the light-emitting layer. The hole-transporting layer is beneficial to transport holes to the light-emitting layer, and the electron-transporting layer is beneficial to transport electrons to the light-emitting layer, so that the output ratio of light is improved further.

### Embodiment Three

An embodiment of the present disclosure provides a display device, comprising: a plurality of sub-pixels, a sub-pixel comprises any OLED device provided in embodiment two.

The display device can comprise monochromatic OLED devices to realize be monochromatic display, or comprise a red OLED device, a green OLED device and a blue OLED device to achieve color display.

The display device can be a display device such as an OLED (Organic Light-Emitting Diode) display etc. or can comprise any products or components having display function as follows: TV set, digital camera, mobile phone, panel computer or the like. The display device can increase the output of light while reducing the reflection of external light.

Optionally, all polarization optical assemblies of OLED devices are in an integrated structure. That is, all polarization optical assemblies contained in the display device are formed by one time film-forming technology. For example, the polarization optical assemblies comprise cholesteric liquid crystal layers, λ/4 wave plates and linear polarizers, then all the cholesteric liquid crystal layers of the polarization optical assemblies are formed by one time film-forming technology, and all the λ/4 wave plates of the polarization optical assemblies are formed by one time film-forming technology, and all the linear polarizers of the polarization optical assemblies are formed by one time film-forming technology. In this way, the difficulty and cost of manufacturing can be reduced.

### Embodiment Four

An embodiment of the present disclosure provides a preparation method of OLED device, and the preparation method of OLED device comprises:

S10: providing a light-emitting element; and

S20: forming a polarization optical assembly on a light-emitting side of the light-emitting element.

For example, in step S10, providing the light-emitting element comprises:

S101: providing a base substrate; and

S102: forming an anode, an organic functional layer and a cathode sequentially on the base substrate.

For example, in step S102, light emitted by the organic functional layer exits at least through the cathode, and the material of the cathode for example can be metal or metal alloy, however the embodiments of the present disclosure are not limited in this aspect.

For example, in step S20, forming the polarization optical assembly on the light-emitting side of the light-emitting elements comprises: forming the polarization optical assembly on a side of the cathode away from the organic functional layer, wherein a cholesteric liquid crystal layer of the polarization optical assembly is able to reflect part of the light emitted by the organic functional layer.

Optionally, forming the polarization optical assembly specifically comprises: sequentially forming the cholesteric liquid crystal layer, a λ/4 wave plate and a linear polarizer on the side away from the organic functional layer of the cathode.

When the OLED device formed by the method is applied in a display device, the display device thus obtained can increase the output of light while reducing the reflection of external light.

An embodiment of the present disclosure provides a polarization optical assembly, an OLED device and a preparation method thereof, a display device. The polarization optical assembly comprises: a cholesteric liquid crystal layer, a λ/4 wave plate and a linear polarizer, wherein the λ/4 wave plate is between the cholesteric liquid crystal layer and the linear polarizer, and an angle exists between a fast axis or a slow axis of the λ/4 wave plate and a transmission axis of the linear polarizer, and polarized light formed by external light sequentially passing the linear polarizer and the λ/4 wave plate is able to pass through the cholesteric liquid crystal layer. When the above-mentioned polarization optical assembly is applied in a display device, after the light R emitted by the organic functional layer (the light R can be divided into left-helically polarized light and right-helically polarized light according to the ratio of 1:1) passes through the cholesteric liquid crystal layer (the description is conducted by taking as an example left-helical polarized light), left-helical polarized light W1 passes through and right-helical polarized light W2 is reflected. On the one hand, the left-helical polarized light W1 is changed into linearly polarized light P3 whose polarization direction is parallel to the polarization direction of the linear polarizer after passing through the λ/4 wave plate, and the light P3 reaches the external environment after passing through the linear polarizer; on the other hand, after right-helical polarized light W2 is reflected by the cholesteric liquid crystal layer (left-helical), it changes its direction of propagation, and is transmitted onto the cathode 1 and then changed into left-helical polarized light W3 after being reflected by the cathode 1. At this time, the left-helically polarized light W3 can pass through the cholesteric liquid crystal layer 8 (left-helical) and then is changed into linearly polarized light P4 whose polarization direction is parallel to polarization direction of the linear polarizer after passing through the λ/4 wave plate, and the linearly polarized light P4 reaches the external environment after passing through the linear polarizer. An embodiment of the present disclosure allows part of the light emitted by the organic functional layer, which part would not be available originally, to be transmitted to the outside re-used by adding the cholesteric liquid crystal layer between the cathode and the λ/4 wave plate, notably increasing the output of light and can guarantee lower reflectivity to external light at the same time.

What have been described above are only specific implementations of the present disclosure, the protection scope of the present disclosure is not limited thereto. The protection scope of the present disclosure should be based on the protection scope of the claims.

The application claims priority to the Chinese patent application No. 201610539561.8, filed on Jul. 8, 2016, the entire disclosure of which is incorporated herein by reference as part of the present application.

1. A polarization optical assembly, comprising: a cholesteric liquid crystal layer, a λ/4 wave plate and a linear polarizer, wherein the λ/4 wave plate is between the cholesteric liquid crystal layer and the linear polarizer, and an angle exists between a fast axis or a slow axis of the λ/4 wave plate and a transmission axis of the linear polarizer, and polarized light formed by external light sequentially passing the linear polarizer and the λ/4 wave plate is able to pass through the cholesteric liquid crystal layer.

2. The polarization optical assembly according to claim 1, wherein the cholesteric liquid crystal layer is a polymer film formed through polymerization of cholesteric liquid crystals.

3. The polarization optical assembly according to claim 1, wherein the cholesteric liquid crystal layer comprises at least two types of cholesteric liquid crystals with different pitches.

4. The polarization optical assembly according to claim 1, wherein the cholesteric liquid crystal layer comprises a plurality of sub-layers, and pitches of all the sub-layers are distributed in a gradient along a thickness direction.

5. The polarization optical assembly according to claim 1, wherein the cholesteric liquid crystal layer comprises cholesteric liquid crystals with a single pitch.

6. The polarization optical assembly according to claim 1, wherein the angle between the fast axis or the slow axis of the λ/4 wave plate and the transmission axis of the linear polarizer is 45°.

7. An organic light-emitting diode (OLED) device, comprising a light-emitting element and the polarization optical assembly according to claim 1,
wherein the polarization optical assembly is on a light-emitting side of the fight-emitting element.

8. The OLED device according to claim 7, wherein the light-emitting element comprises: a cathode, an anode and an organic functional layer arranged between the cathode and the anode, and light emitted by the organic functional layer exits at least through the cathode.

9. The OLED device according to claim 8, wherein the polarization optical assembly are on a side of the cathode away from the organic functional layer, and the cholesteric liquid crystal layer of the polarization optical assembly is configured to reflect part of the light emitted by the organic functional layer.

10. The OLED device according to claim 8, wherein the organic functional layer comprises:
a light-emitting layer,
a hole injection layer arranged between the light-emitting layer and the anode, and
an electron injection layer arranged between the light-emitting layer and the cathode.

11. The OLED device according to claim 10, wherein the organic functional layer further comprises:
a hole-transporting layer arranged between the hole injection layer and the light-emitting layer, and
an electron-transporting layer arranged between the electron injection layer and the light-emitting layer.

12. A display device, comprising: a plurality of sub-pixels, wherein each of the sub-pixels comprises the OLED device according to claim 7.

13. The display device according to claim 12, wherein all polarization optical assemblies of OLED devices of the plurality of sub-pixels are in an integrated structure.

14. A preparation method of an organic light-emitting diode (OLED) device, comprising:
providing a light-emitting element, and
forming a polarization optical assembly on a light-emitting side of the light-emitting element.

15. The preparation method of the OLED components according to claim 14, wherein providing the light-emitting element comprises:
providing a base substrate;
forming an anode, an organic functional layer and a cathode sequentially on the base substrate, wherein light emitted by the organic functional layer exits at least through the cathode.

16. The preparation method of the OLED components according to claim 15, wherein forming the polarization optical assembly on the light-emitting side of the light-emitting elements comprises:
forming the polarization optical assembly on a side of the cathode away from the organic functional layer,
wherein a cholesteric liquid crystal layer of the polarization optical assembly is configured to be able to reflect part of the light emitted by the organic functional layer.

17. The polarization optical assembly according to claim 3, wherein the cholesteric liquid crystal layer comprises a plurality of sub-layers, and pitches of all the sub-layers are distributed in a gradient along a thickness direction.

18. The polarization optical assembly according to claim 3, wherein the angle between the fast axis or the slow axis of the λ/4 wave plate and the transmission axis of the linear polarizer is 45°.
